(19) United States
(12) Patent Application Publication
(10) Pub. No.: US 2026/0248015 A1
(43) Pub. Date: Aug. 20, 2026

(54) JOINING LAYER AND JOINING STRUCTURE

(71) Applicant: TDK CORPORATION, Tokyo (JP)

(72) Inventors: Tomohisa MITOSE, Tokyo (JP); Susumu TANIGUCHI, Tokyo (JP)

(73) Assignee: TDK CORPORATION, Tokyo (JP)

(21) Appl. No.: 19/164,261

(22) PCT Filed: Mar. 13, 2024
(86) PCT No.: PCT/JP2024/009882

§ 371 Date: Sep. 11, 2025

(30) Foreign Application Priority Data
Mar. 17, 2023 (JP) 2023-043263

(51) Int. Cl. H10W 72/20; H05K 1/11; H05K 1/181

(52) U.S. Cl. CPC H10W 72/223; H05K 1/111; H05K 1/181; H10W 72/234; H10W 72/235; H10W 72/244; H10W 72/245; H10W 72/252; H10W 72/2528

(57) ABSTRACT

A joining layer is a joining layer for joining an electronic component and a substrate electrode, and the joining layer has a width narrower than a width of the substrate electrode at least at a joint portion with the substrate electrode.

### TECHNICAL FIELD

The present disclosure relates to a joining layer and a joining structure.

### BACKGROUND ART

With the miniaturization and thinning of electronic devices, there is a growing demand for high-density mounting of electronic components. For high-density mounting, flip-chip mounting, in which electronic components such as semiconductor chips are directly mounted on a circuit board in a bare state without being sealed with resin or the like, has been adopted (for example, Patent Literature 1). In recent years, as a method advantageous for high-density mounting at low cost, thermocompression bonding, ultrasonic bonding, and the like using metal bumps such as plated bumps formed on semiconductor chips by a plating method, or stud bumps in which gold balls formed at the tips of gold wires are fixed on pads, have been attracting attention (for example, Patent Literature 1).

### CITATION LIST

### Patent Literature

[Patent Literature 1] Japanese Patent Application Publication No. 2003-200289

### SUMMARY OF INVENTION

### Technical Problem

Here, when the mounting density of electronic components is improved, the pitch between substrate electrodes becomes narrower. Thus, due to the narrow pitch of the substrate electrodes, there is a problem that a short circuit between terminals occurs via the joining layers in subsequent processes such as secondary mounting or repair of the electronic components.

An object of the present disclosure is to provide a joining layer and a joining structure enable to suppress a short circuit between terminals in subsequent processes such as secondary mounting or repair of electronic components, which is caused by the narrow pitch of substrate electrodes accompanying the improvement in mounting density.

### Solution to Problem

A joining layer according to the present disclosure is a joining layer for joining an electronic component and a substrate electrode, and has a width narrower than a width of the substrate electrode at least at a joint portion with the substrate electrode.

A joining structure according to the present disclosure is a joining structure for joining an electronic component and a substrate, including a first joining layer joining the electronic component and a first substrate electrode, and a second joining layer arranged adjacent to the first joining layer and spaced apart from the first joining layer in a width direction and joining the electronic component and a second substrate electrode. At least one of the first joining layer and the second joining layer is, at a joint portion with one of the substrate electrodes, arranged at a position spaced further apart from the other joining layer than the substrate electrode corresponding thereof in the width direction.

### Advantageous Effects of Invention

According to the present disclosure, it is possible to provide a joining layer and a joining structure enable to suppress a short circuit between terminals in subsequent processes such as secondary mounting or repair of electronic components, which is caused by the narrow pitch of substrate electrodes accompanying the improvement in mounting density.

### BRIEF DESCRIPTION OF DRAWINGS

FIG. 1 is a schematic cross-sectional view showing a mounting substrate including a joining layer and a joining structure according to one embodiment of the present disclosure.

FIG. 2 is a schematic cross-sectional view showing a specific example of the joining layer and the joining structure according to one embodiment of the present disclosure.

FIG. 3 is an enlarged view of the vicinity of the joining layer.

FIG. 4 is a schematic cross-sectional view showing a mounting substrate including a joining layer and a joining structure according to a comparative example.

FIG. 5 is a schematic cross-sectional view showing a mounting substrate including a joining layer and a joining structure according to a modification.

FIG. 6 is a schematic cross-sectional view showing a mounting substrate including a joining layer and a joining structure according to a modification.

FIG. 7 is a schematic cross-sectional view showing a mounting substrate including a joining layer and a joining structure according to a modification.

FIG. 8 is a schematic cross-sectional view showing a mounting substrate including a joining layer and a joining structure according to a modification.

FIG. 9 is a schematic cross-sectional view showing a mounting substrate including a joining layer and a joining structure according to a modification.

FIG. 10 is a schematic cross-sectional view showing a mounting substrate including a joining layer and a joining structure according to a modification.

### DESCRIPTION OF EMBODIMENTS

A joining layer according to the present disclosure has a width narrower than a width of a substrate electrode at least at a joint portion with the substrate electrode. That is, in a state after joining, the width at the joint portion is narrower than the width of the substrate electrode to be joined. In this case, even if deformation of the joining layer due to a load or melting occurs in a subsequent process such as secondary mounting or repair, widening of the joining layer in the width direction can be suppressed. Therefore, it is possible to suppress the deformed joining layer from coming into contact with a joining layer for another substrate electrode. From the above, it is possible to suppress a short circuit between terminals in subsequent processes such as secondary mounting or repair of an electronic component.

The substrate electrode may include a barrier layer, and the joining layer may have a width narrower than a width of the barrier layer at the joint portion. In this case, even when the substrate electrode includes the barrier layer, the same effects as described above can be achieved.

The joining layer may contain Sn. A joining layer containing Sn is soft and has a low melting point. Therefore, it is easily deformed in a subsequent process, and the risk of a short circuit between terminals is high. However, by having the above structure, the short circuit between terminals in the subsequent process can be suppressed.

The substrate electrode may include a barrier layer, the joining layer may have a body portion and an intermetallic compound layer formed between the body portion and the barrier layer, and the intermetallic compound layer may contain an intermetallic compound composed of a first metal element contained in the body portion and a second metal element contained in the barrier layer. In this case, the presence of the intermetallic compound composed of the constituent metal of the barrier layer and the constituent metal of the joining layer can improve the adhesion strength between the barrier layer and the joining layer.

In the joining structure according to the present disclosure, at least one of the first joining layer and the second joining layer is, at a joint portion with one of the substrate electrodes, arranged at a position spaced further apart from the other joining layer than the substrate electrode corresponding thereof in the width direction. That is, in a state after joining, the joint portion is arranged at a position farther apart from the other joining layer than the substrate electrode to be connected. In this case, even if deformation of the joining layer due to a load or melting occurs in a subsequent process such as secondary mounting or repair, widening of the one joining layer in the width direction can be suppressed. Therefore, it is possible to suppress the deformed one joining layer from coming into contact with the other joining layer. From the above, it is possible to suppress a short circuit between terminals in subsequent processes such as secondary mounting or repair of an electronic component.

When a separation distance in the width direction between the one substrate electrode and the other substrate electrode is a first dimension, and a separation distance in the width direction between the joint portion of the one joining layer and the other joining layer is a second dimension, the second dimension may be larger than the first dimension. In this case, even if the one joining layer is deformed, it can be suppressed from coming into contact with the other joining layer.

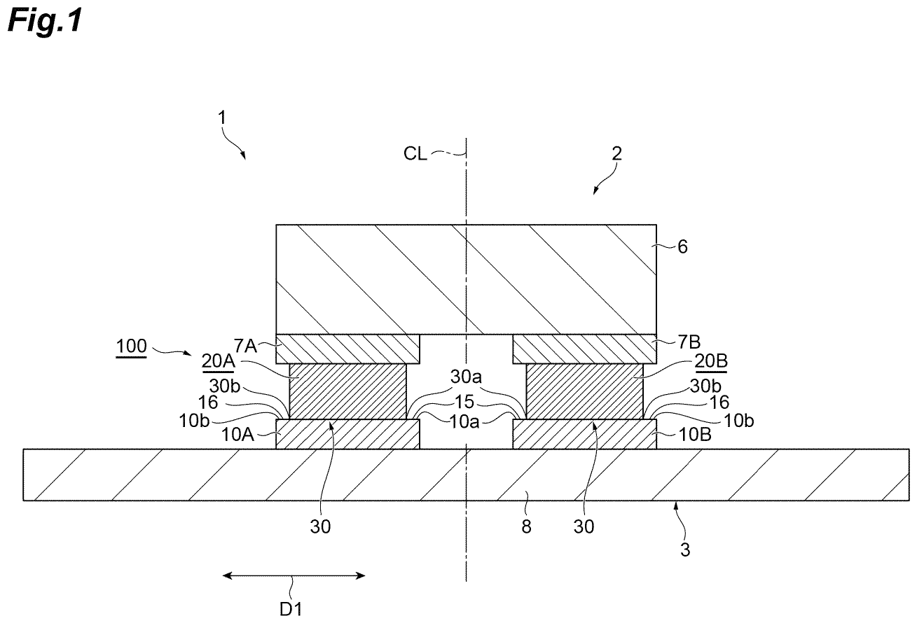

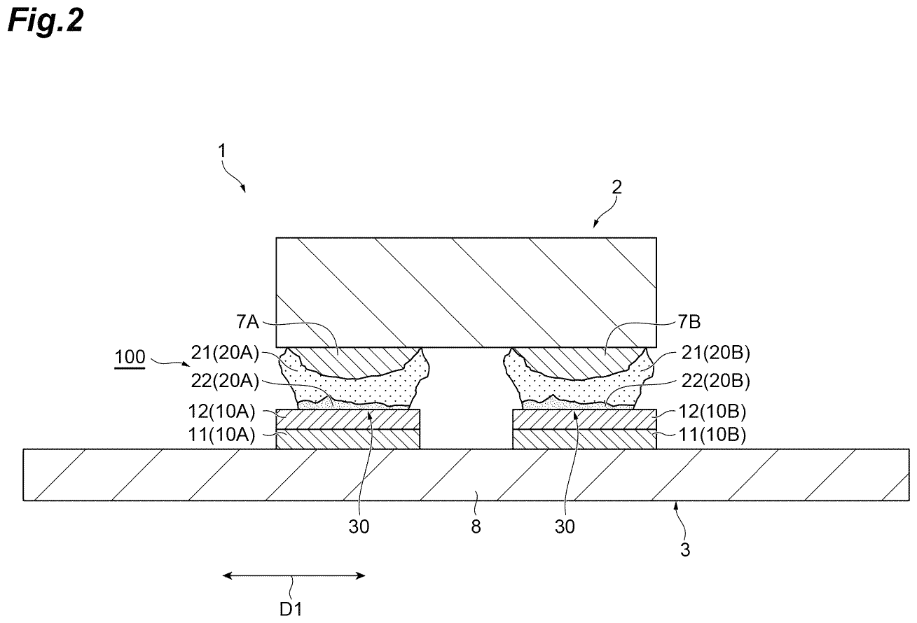

With reference to FIGS. 1 and 2, joining layers 20A and 20B and a joining structure 100 according to one embodiment of the present disclosure will be described. FIG. 1 is a schematic cross-sectional view showing a mounting substrate 1 including the joining layers 20A and 20B and the joining structure 100 according to the embodiment of the present disclosure. FIG. 2 is a schematic cross-sectional view showing a specific example of the joining layers 20A and 20B and the joining structure 100 according to the embodiment of the present disclosure.

As shown in FIG. 1, the mounting substrate 1 includes an electronic component 2 and a substrate 3. The mounting substrate 1 is configured by mounting the electronic component 2 on the substrate 3 via the joining structure 100.

The electronic component 2 includes a body portion 6, a first terminal 7A, and a second terminal 7B. The body portion 6 is a member for exhibiting a function of the electronic component 2. The terminals 7A and 7B are metal portions formed on a main surface of the body portion 6. The terminals 7A and 7B are arranged adjacent to each other while being spaced apart in a width direction D1. The material of the terminals 7A and 7B may be any one metal of Au, Cu, Ni, Ag, and Pd, or an alloy selected from at least two of them. The electronic component 2 is configured by, for example, a micro-LED or the like. The micro-LED is a component that emits light in response to an input from the substrate 3.

The substrate 3 includes a base material 8, a first substrate electrode 10A, and a second substrate electrode 10B. The base material 8 is a body portion having a plate shape of the substrate 3. As the base material 8, a printed circuit board for mounting each conductor pattern and each electronic component on a main surface may be adopted. As a material of the base material 8, a known resin material or ceramic material used for a printed circuit board may be adopted. The substrate electrodes 10A and 10B are metal portions formed on the main surface of the base material 8. The substrate electrodes 10A and 10B are arranged adjacent to each other while being spaced apart in the width direction D1. In the example shown in FIG. 2, each of the substrate electrodes 10A and 10B includes an electrode layer 11 formed on the substrate 3, and a barrier layer 12 formed on an upper surface of the electrode layer 11. As a material of the electrode layer 11, Ni, Cu, Ti, Cr, Al, Mo, Pt, Au, or an alloy selected from at least two of them is adopted. The barrier layer 12 contains a second metal element. As the second metal element, Ti, Cu, Ni, Al, Mo, Cr, Ag, or the like is adopted.

The joining structure 100 includes a first joining layer 20A and a second joining layer 20B. The first joining layer 20A is a layer for joining the electronic component 2 and the first substrate electrode 10A. The second joining layer 20B is a layer for joining the electronic component 2 and the second substrate electrode 10B. The second joining layer 20B is arranged adjacent to the first joining layer 20A while being spaced apart in the width direction D1.

In the example shown in FIG. 2, each of the joining layers 20A and 20B has a body portion 21 and an intermetallic compound layer 22. The body portion 21 is a portion for joining the electronic component 2 and the substrate electrodes 10A and 10B. Before assembly, the substrate 3 may include the body portion 21 in a state of being arranged on the upper surfaces of each of the substrate electrodes 10A and 10B. The body portion 21 functions as solder. At the time of assembly, after the substrate electrodes 10A and 10B, the body portion 21, and the terminals 7A and 7B are layered, solder joining is performed. The body portion 21 contains a first metal element. In the body portion 21, there occurs diffusion of elements from the terminals on the electronic component side and the barrier layer between before and after joining. Therefore, the types of materials contained are different between “the body portion 21 before joining” and “the body portion 21 after joining”. Specifically, as the first metal element of the body portion 21 before joining, Sn, Bi, In, Au, Cu, Al, Ag, or the like is adopted. As the first metal element of the body portion 21 after joining, Sn, Bi, In, Au, Cu, Al, Ag, Ni, Ti, Mo, Cr, or the like is adopted.

The intermetallic compound layer 22 is a layer formed between the body portion 21 and the barrier layer 12. The intermetallic compound layer 22 contains an intermetallic compound composed of the first metal element contained in the body portion 21 and the second metal element contained in the barrier layer 12. The intermetallic compound layer 22 is formed by diffusion of the metal material of the barrier layer 12 into the body portion 21 when the metal material of the body portion 21 is arranged on the barrier layer 12 at the time of assembly. Alternatively, after forming the intermetallic compound layer 22 before assembly, the body portion 21 (the above-mentioned “the body portion 21 after joining”) may be attached.

As shown in FIG. 1, each of the joining layers 20A and 20B has a width narrower than the width of each of the substrate electrodes 10A and 10B at least at a joint portion 30 with each of the substrate electrodes 10A and 10B. In the diagram shown in FIG. 1, each of the joining layers 20A and 20B has a width narrower than the width of the substrate electrodes 10A and 10B over the entire region in the vertical direction. As in the example shown in FIG. 2, when each of the substrate electrodes 10A and 10B has the barrier layer 12, each of the joining layers 20A and 20B has a width narrower than the width of the barrier layer 12 at the joint portion 30.

Further, the first joining layer 20A (one joining layer) is, at the joint portion 30 with the first substrate electrode 10A (one substrate electrode), arranged at a position spaced further apart from the second joining layer 20B (the other joining layer) than the first substrate electrode 10A in the width direction D1. The second joining layer 20B is, at the joint portion 30 with the second substrate electrode 10B, arranged at a position spaced further apart from the first joining layer 20A than the second substrate electrode 10B in the width direction D1.

When a center line CL in the width direction D1 of the electronic component 2 is set, a side close to the center line CL is referred to as an inner side in the width direction D1, and a side apart from the center line CL is referred to as an outer side in the width direction D1. An inner end portion 30a in the width direction D1 of the joint portion 30 of the first joining layer 20A is arranged on the outer side in the width direction D1 with respect to an inner end portion 10a in the width direction D1 of the first substrate electrode 10A. An inner end portion 30a in the width direction D1 of the joint portion 30 of the second joining layer 20B is arranged on the outer side in the width direction D1 with respect to an inner end portion 10a in the width direction D1 of the second substrate electrode 10B. As a result, step surfaces 15 exposed from the joining layers 20A and 20B are formed in the vicinity of the inner end portions 10a in the width direction D1 of the substrate electrodes 10A and 10B.

In the present embodiment, an outer end portion 30b in the width direction D1 of the joint portion 30 of the first joining layer 20A is arranged on the inner side in the width direction D1 with respect to an outer end portion 10b in the width direction D1 of the first substrate electrode 10A. An outer end portion 30b in the width direction D1 of the joint portion 30 of the second joining layer 20B is arranged on the inner side in the width direction D1 with respect to an outer end portion 10b in the width direction D1 of the second substrate electrode 10B. As a result, step surfaces 16 exposed from the joining layers 20A and 20B are formed in the vicinity of the outer end portions 10b in the width direction D1 of the substrate electrodes 10A and 10B.

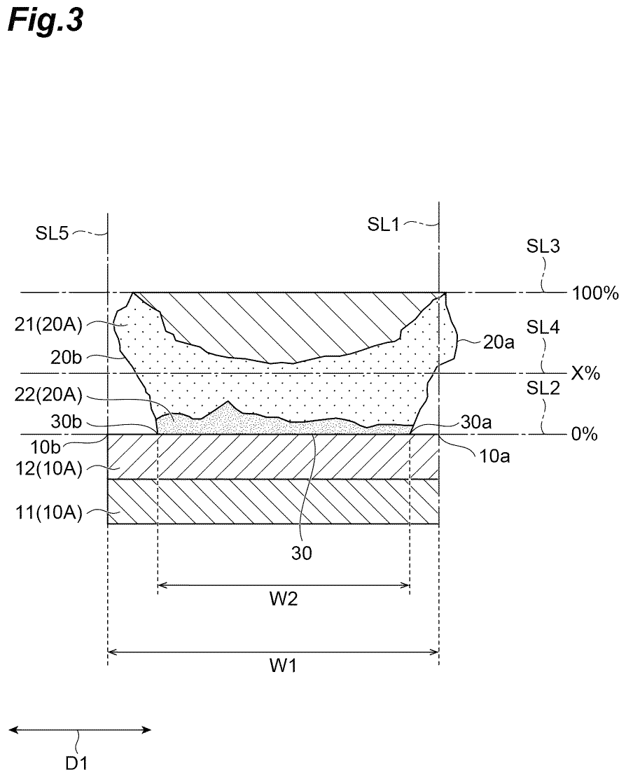

The relationship between the sizes of the joining layers 20A and 20B and the substrate electrodes 10A and 10B will be described in more detail with reference to FIG. 3. Although FIG. 3 shows the first joining layer 20A, the same goes for the second joining layer 20B. In FIG. 3, the right side corresponds to the inner side in the width direction D1, and the left side corresponds to the outer side in the width direction D1.

The width W1 of the first substrate electrode 10A is defined by a dimension in the width direction D1 between the end portion 10a and the end portion 10b of the first substrate electrode 10A. The end portion 10a is set at the innermost position in the width direction D1 on the upper surface of the first substrate electrode 10A. The end portion 10b is set at the outermost position in the width direction D1 on the upper surface of the first substrate electrode 10A. The joint portion 30 of the first joining layer 20A is a boundary portion of the first joining layer 20A with respect to the first substrate electrode 10A. The width W2 at the joint portion 30 is defined by a dimension in the width direction D1 between the end portion 30a and the end portion 30b of the joint portion 30. The end portion 30a is set at the innermost position in the width direction D1 of the joint portion 30. The end portion 30b is set at the outermost position in the width direction D1 of the joint portion 30. In the present embodiment, a lower surface of the intermetallic compound layer 22 serves as the joint portion 30. When the width W1 and the width W2 are defined as the above, a relationship of W1>W2 is established. If W2/W1≤0.88, even if an upper portion of the first joining layer 20A protrudes, the joining layer wets to widen on the barrier layer, even if deformation of the joining layer due to a load or melting occurs in a subsequent process such as secondary mounting or repair. Therefore, the first joining layer 20A is less likely to expand inward, which leads to suppression of short circuits. In particular, W2/W1≤0.77.

As shown in FIG. 3, a reference line SL1 extending in the vertical direction passing through the end portion 10a of the first substrate electrode 10A is set. A reference line SL2 extending in the width direction D1 passing through a lower end of the first joining layer 20A (here, the joint portion 30) is set. A reference line SL3 extending in the width direction D1 passing through an upper end of the first joining layer 20A is set. To describe a region in a height direction with the lower end of the first joining layer 20A as a reference, the position of the reference line SL2 is set as 0% position, and a range from the reference line SL2 to the reference line SL3 is set as 100% region. Further, when a reference line SL4 is arbitrarily set between the reference line SL2 and the reference line SL3, a range from the reference line SL2 to the reference line SL4 is set as X% region. A reference line SL5 extending in the vertical direction passing through the end portion 10b of the first substrate electrode 10A is set.

A part of an inner side surface 20a in the width direction D1 of the first joining layer 20A may protrude inward in the width direction D1 from the reference line SL1. The side surface 20a may not protrude from the reference line SL1 in a region near the joint portion 30. For example, the side surface 20a may not protrude from the reference line SL1 in 50% region from the reference line SL2, or the side surface 20a may not protrude from the reference line SL1 in 10% region, or the side surface 20a may not protrude from the reference line SL1 in 50% region. Note that the same relationship holds true between an outer side surface 20b in the width direction D1 and the reference line SL5.

Next, functions and effects of the joining layers 20A and 20B and the joining structure 100 according to the present embodiment will be described.

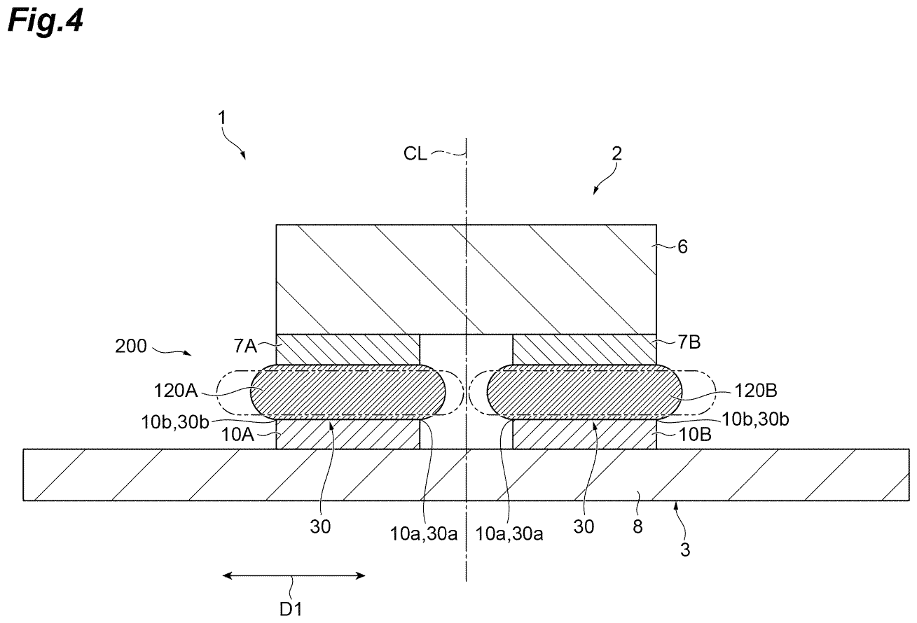

First, with reference to FIG. 4, joining layers 120A and 120B and a joining structure 200 according to a comparative example will be described. The joining layers 120A, 120B have the same width as the substrate electrodes 10A and 10B. Therefore, the joining layers 120A and 120B after joining are in a state of being close to each other on the inner side in the width direction D1. As shown by a two-dot chain line in FIG. 4, if deformation of the joining layer due to a load or melting occurs in a subsequent process such as secondary mounting or repair, the widening of the joining layers 120A and 120B in the width direction becomes even larger. As a result, the deformed joining layer 120A comes into contact with the joining layer 120B for the other substrate electrode 10B, causing a short circuit between terminals.

In contrast, each of the joining layers 20A and 20B according to the present embodiment has a width narrower than the width of the substrate electrodes 10A and 10B at least at the joint portion 30 with the substrate electrodes 10A and 10B. That is, in a state after joining, the width of each of the joining layers 20A and 20B at the joint portion 30 is narrower than the width of the substrate electrodes 10A and 10B to be joined. In this case, even if deformation of the joining layer due to a load or melting occurs in a subsequent process such as secondary mounting or repair, widening of the joining layers 20A and 20B in the width direction can be suppressed. Therefore, it is possible to suppress the deformed joining layer 20A from coming into contact with the joining layer 20B for the other substrate electrode 10B. From the above, it is possible to suppress a short circuit between terminals in subsequent processes such as secondary mounting or repair of the electronic component 2.

Each of the substrate electrodes 10A and 10B may include the barrier layer 12, and each of the joining layers 20A and 20B may have a width narrower than the width of the barrier layer 12 at the joint portion 30. In this case, even when each of the substrate electrodes 10A and 10B have the barrier layer 12, the same effects as described above can be achieved.

Each of the joining layers 20A and 20B may contain Sn. The joining layers 20A and 20B containing Sn are soft and have a low melting point. Therefore, it is easily deformed in a subsequent process, and the risk of a short circuit between terminals is high. However, by having the above structure, a short circuit between terminals in a subsequent process can be suppressed.

Each of the substrate electrodes 10A and 10B may include the barrier layer 12, each of the joining layers 20A and 20B may have the body portion 21 and the intermetallic compound layer 22 formed between the body portion 21 and the barrier layer 12, and the intermetallic compound layer 22 may contain the intermetallic compound composed of the first metal element contained in the body portion 21 and the second metal element contained in the barrier layer 12. In this case, the presence of the intermetallic compound composed of the constituent metal of the barrier layer 12 and the constituent metal of the joining layers 20A and 20B can improve the adhesion strength between the barrier layer 12 and the joining layers 20A and 20B.

The joining structure 100 according to the present embodiment is the joining structure 100 for joining the electronic component 2 and the substrate 3, including the first joining layer 20A for joining the electronic component 2 and the first substrate electrode 10A, and the second joining layer 20B arranged adjacent to the first joining layer 20A and spaced apart from the first joining layer 20A in the width direction D1, for joining the electronic component 2 and the second substrate electrode 10B. The first joining layer 20A is, at the joint portion 30 with the first substrate electrode 10A, arranged at the position spaced further apart from the second joining layer 20B than the first substrate electrode 10A in the width direction D1.

In the joining structure 100 according to the present embodiment, the first joining layer 20A is, at the joint portion 30 with the first substrate electrode 10A, arranged at the position spaced further apart from the second joining layer 20B than the first substrate electrode 10A in the width direction D1. That is, in a state after joining, the joint portion 30 is arranged at a position farther from the second joining layer 20B than the first substrate electrode 10A to be connected. In this case, even if deformation of the second joining layer 20B due to a load or melting occurs in a subsequent process such as secondary mounting or repair, widening of the first joining layer 20A in the width direction D1 can be suppressed. Therefore, it is possible to suppress the deformed first joining layer 20A from coming into contact with the second joining layer 20B. From the above, it is possible to suppress a short circuit between terminals in subsequent processes such as secondary mounting or repair of the electronic component 2. Note that this description assumes that the first joining layer 20A is the “one joining layer” in the claims, but the same functions and effects can be achieved even if the second joining layer 20B is regarded as the “one joining layer” in the claims.

The present disclosure is not limited to the above-described embodiment.

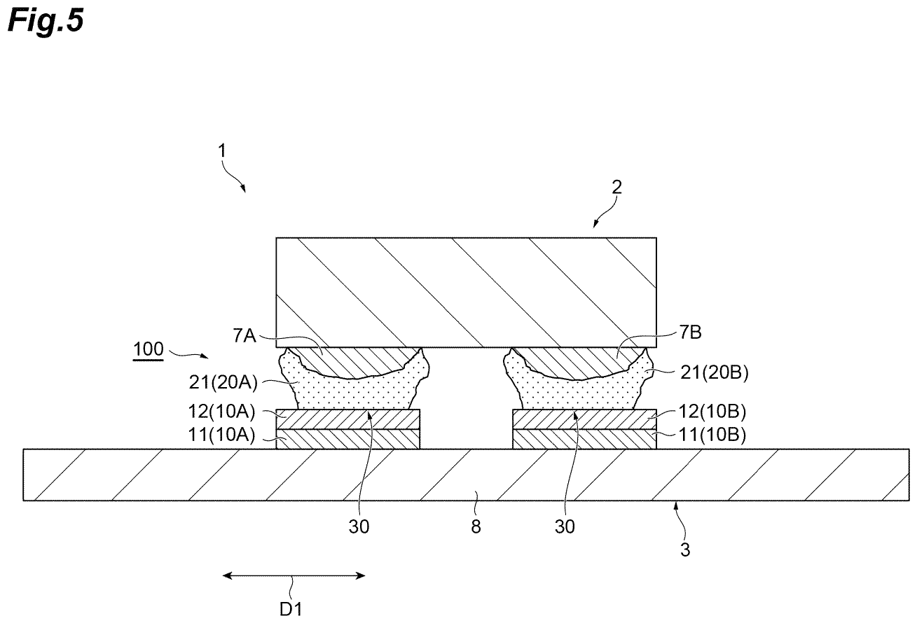

The structure in each layer is not limited to that of the above-described embodiment. For example, as shown in FIG. 5, a configuration in which the intermetallic compound layer 22 is omitted from the configuration shown in FIG. 2 may be adopted.

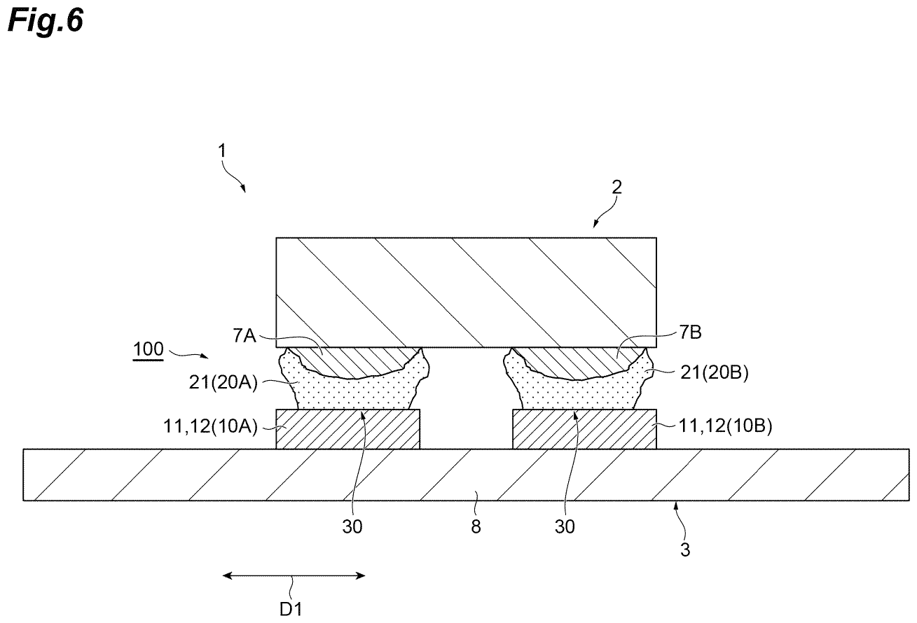

Further, as shown in FIG. 6, substrate electrodes 10A and 10B related to a single layer may be adopted for the configuration shown in FIG. 5. For example, the substrate electrodes 10A and 10B may be a single layer of the electrode layer 11, or a single layer of the barrier layer 12.

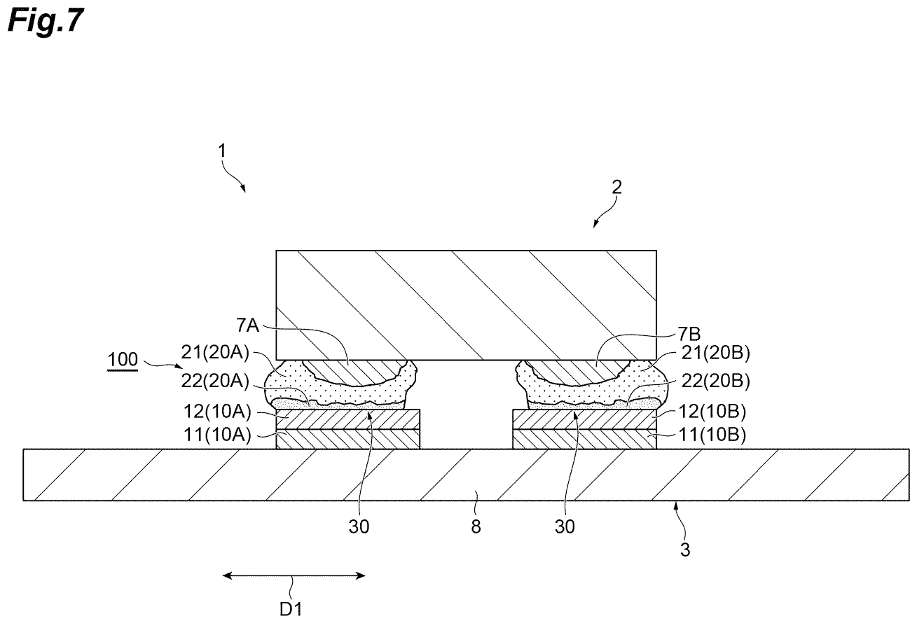

In the above-described embodiment, the outer end portions in the width direction D1 of the joining layers 20A and 20B were arranged on the inner side in the width direction D1 with respect to the outer end portions in the width direction D1 of the substrate electrodes 10A and 10B. However, as shown in FIG. 7, this relationship does not necessarily have to be established. That is, the structure for suppressing the widening of the joining layers 20A and 20B in a subsequent process only needs to be adopted on the inner side in the width direction D1, where the possibility of a short circuit between terminals is high.

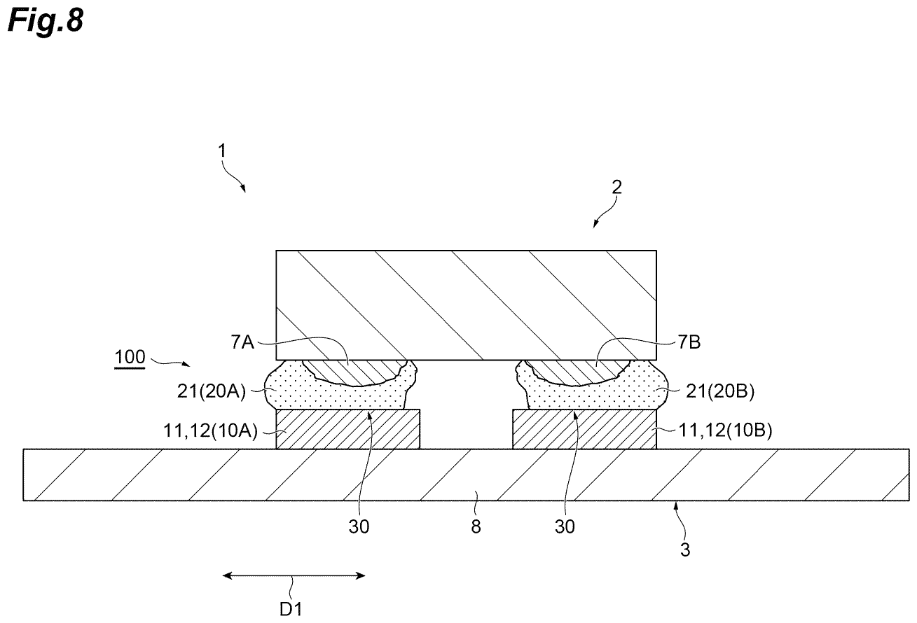

Note that, as shown in FIG. 8, the intermetallic compound layer 22 may be omitted from the configuration shown in FIG. 7, or the substrate electrodes 10A and 10B related to a single layer may be adopted.

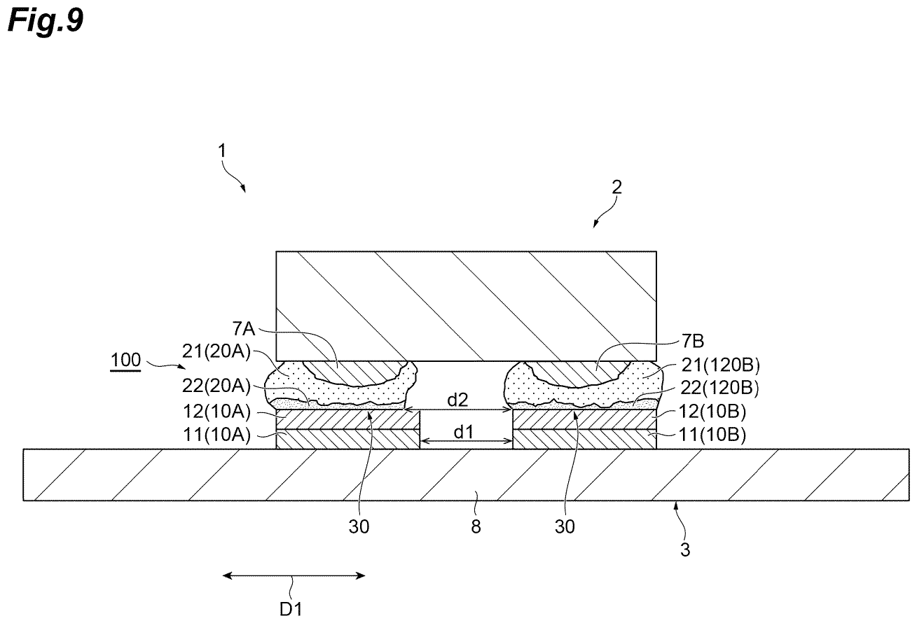

Further, in the configurations shown in FIGS. 2 and 5 to 8, the structure for suppressing a short circuit between terminals was adopted on both sides of the first joining layer 20A and the second joining layer 20B. However, the structure for suppressing a short circuit between terminals only needs to be adopted in at least one of the first joining layer 20A and the second joining layer 20B. For example, as shown in FIG. 9, a structure for suppressing a short circuit between terminals may be adopted on the inner side in the width direction D1 of the first joining layer 20A, and a structure for suppressing a short circuit between terminals may not be adopted on the inner side in the width direction D1 of the second joining layer 20B.

In this case, when a separation distance in the width direction D1 between the first substrate electrode 10A and the second substrate electrode 10B is a first dimension d1, and a separation distance in the width direction D1 between the joint portion 30 of the first joining layer 20A and the second joining layer 20B is a second dimension d2, the second dimension d2 may be larger than the first dimension d1. In this case, even if the first joining layer 20A is deformed, it can be suppressed from coming into contact with the second joining layer 20B. Note that a structure for suppressing a short circuit between terminals may be adopted on the inner side in the width direction D1 of the second joining layer 20B, and a structure for suppressing a short circuit between terminals may not be adopted on the inner side in the width direction D1 of the first joining layer 20A.

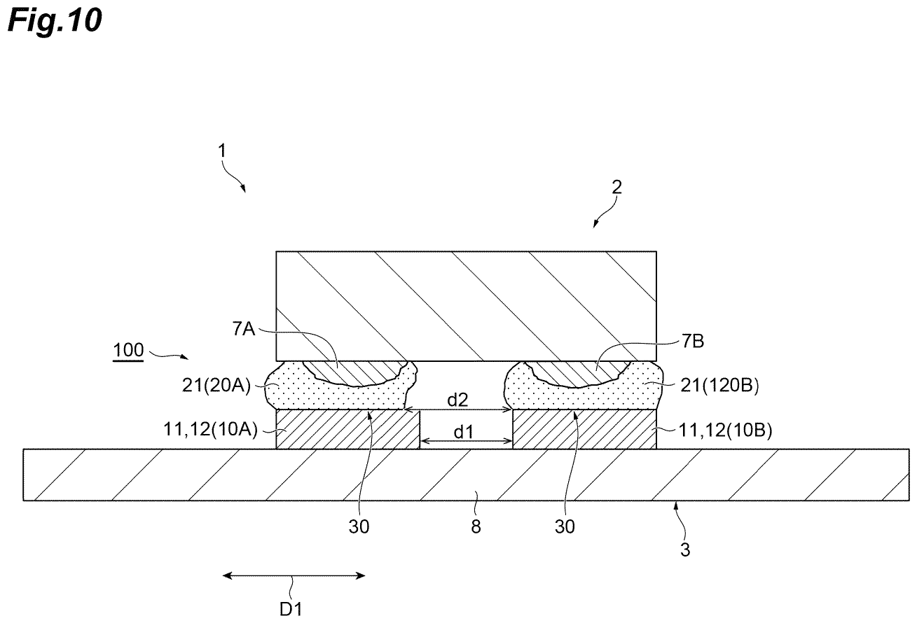

Note that, as shown in FIG. 10, the intermetallic compound layer 22 may be omitted from the configuration shown in FIG. 9, or the substrate electrodes 10A and 10B related to a single layer may be adopted.

### Aspect 1

A joining layer for joining an electronic component and a substrate electrode,
wherein the joining layer has a width narrower than a width of the substrate electrode at least at a joint portion with the substrate electrode.

### Aspect 2

The joining layer according to Aspect 1, wherein the substrate electrode includes a barrier layer, and
the joining layer has a width narrower than a width of the barrier layer at the joint portion.

### Aspect 3

The joining layer according to Aspect 1 or 2, comprising Sn.

### Aspect 4

The joining layer according to any one of Aspects 1 to 3, wherein the substrate electrode includes a barrier layer,
the joining layer has a body portion and an intermetallic compound layer formed between the body portion and the barrier layer, and
the intermetallic compound layer contains an intermetallic compound composed of a first metal element contained in the body portion and a second metal element contained in the barrier layer.

### Aspect 5

A joining structure for joining an electronic component and a substrate, the joining structure comprising:
a first joining layer joining the electronic component and a first substrate electrode; and
a second joining layer arranged adjacent to the first joining layer and spaced apart from the first joining layer in a width direction, the second joining layer joining the electronic component and a second substrate electrode,
wherein at least one of the first joining layer and the second joining layer is, at a joint portion with one of the substrate electrodes, arranged at a position spaced further apart from the other joining layer than the substrate electrode corresponding thereof in the width direction.

### Aspect 6

The joining structure according to Aspect 5, wherein when a separation distance in the width direction between the one substrate electrode and the other substrate electrode is a first dimension, and
a separation distance in the width direction between the joint portion of the one joining layer and the other joining layer is a second dimension,
the second dimension is larger than the first dimension.

### REFERENCE SIGNS LIST

2 electronic component
3 substrate
10A first substrate electrode
10B second substrate electrode
11 electrode layer
12 barrier layer
20A first joining layer
20B second joining layer
21 body portion
22 intermetallic compound layer
30 joint portion
100 joining structure

1. A joining layer for joining an electronic component and a substrate electrode, wherein the joining layer has a width narrower than a width of the substrate electrode at least at a joint portion with the substrate electrode.

2. The joining layer according to claim 1, wherein the substrate electrode includes a barrier layer, and the joining layer has a width narrower than a width of the barrier layer at the joint portion.

3. The joining layer according to claim 1, comprising Sn.

4. The joining layer according to claim 1, wherein the substrate electrode includes a barrier layer, the joining layer has a body portion and an intermetallic compound layer formed between the body portion and the barrier layer, and the intermetallic compound layer contains an intermetallic compound composed of a first metal element contained in the body portion and a second metal element contained in the barrier layer.

5. A joining structure for joining an electronic component and a substrate,
the joining structure comprising:
a first joining layer joining the electronic component and a first substrate electrode; and
a second joining layer arranged adjacent to the first joining layer and spaced apart from the first joining layer in a width direction, the second joining layer joining the electronic component and a second substrate electrode,
wherein at least one of the first joining layer and the second joining layer is, at a joint portion with one of the substrate electrodes, arranged at a position spaced further apart from the other joining layer than the substrate electrode corresponding thereof in the width direction.

6. The joining structure according to claim 5, when a separation distance in the width direction between the first substrate electrode and the second substrate electrode is a first dimension, and a separation distance in the width direction between the first joining layer and the second joining layer is a second dimension, the second dimension is larger than the first dimension.
